(19) United States
(12) Patent Application Publication
(10) Pub. No.: US 2014/0261570 A1
(43) Pub. Date: Sep. 18, 2014

(54) SUBSTRATE LIQUID PROCESSING METHOD, SUBSTRATE LIQUID PROCESSING APPARATUS, AND STORAGE MEDIUM

(71) Applicant: Tokyo Electron Limited, Tokyo (JP)

(72) Inventors: Takehiko Orii, Yamanashi (JP); Naoki Shindo, Yamanashi (JP)

(73) Assignee: Tokyo Electron Limited, Tokyo (JP)

(21) Appl. No.: 14/186,131

(22) Filed: Feb. 21, 2014

(30) Foreign Application Priority Data
Mar. 15, 2013 (JP) 2013-053579
Jan. 20, 2014 (JP) 2014-008085

(51) Int. Cl. H01L 21/02

(52) U.S. Cl. CPC H01L 21/02087
USPC 134/31; 134/33; 134/144

(57) ABSTRACT

Disclosed is a substrate liquid processing method. The substrate liquid processing method includes: forming a liquid film of a processing liquid having a diameter smaller than that of the substrate on a surface of a substrate by providing the processing liquid to a central portion of the surface of the substrate from a first nozzle while rotating the substrate around a vertical axis in a horizontal posture; supplying, from a second nozzle, a processing liquid, which is the same as the processing liquid supplied from the first nozzle, to a peripheral edge of the liquid film of the processing liquid formed on the surface by the first nozzle; and moving a position of supplying the processing liquid from the second nozzle to the surface of the substrate toward a peripheral edge of the substrate and as a result, expanding the liquid film of the processing liquid toward the peripheral edge of the substrate.

### CROSS-REFERENCE TO RELATED APPLICATIONS

This application is based on and claims priority from Japanese Patent Applications Nos. 2013-053579 and 2014-008085, filed on Mar. 15, 2013 and Jan. 20, 2014, respectively, with the Japan Patent Office, the disclosures of which are incorporated herein in their entireties by reference.

### TECHNICAL FIELD

The present disclosure relates to a technology of processing a substrate by supplying a processing liquid on the substrate while rotating the substrate.

### BACKGROUND

In performing a liquid processing such as, for example, a chemical liquid processing or a rinse processing, on a substrate such as a semiconductor wafer, it is common to supply a processing liquid to a central portion of the substrate while rotating the substrate around a vertical axis in a horizontal posture. In such a case, the processing liquid supplied to the central portion of the substrate spreads out by a centrifugal force such that the entire surface of the substrate is covered by a liquid film of the processing liquid.

When a portion uncovered by the processing liquid exists on the surface of the substrate, a processing may be performed unevenly, for example, in a chemical liquid processing process. Further, when a rinse processing is carried out on a patterned substrate using de-ionized water (DIW), for example, a processing liquid (e.g., a chemical liquid) used in a previous process, may remain in the pattern or particles may occur due to an insufficient rinse processing.

A surface coverage of a substrate by a processing liquid may be influenced by a rotation speed of the substrate and a flow rate of the processing liquid. The higher rotation speed of the substrate may facilitate the spreading of the liquid film of the processing liquid but may cause undesired scattering of the processing liquid (e.g., scattering out of a cup). The higher processing liquid flow rate may facilitate the spreading of the liquid film of the processing liquid over the entire surface of the substrate but may increase the use amount of the processing liquid. In particular, when the surface of the substrate is highly hydrophobic, it is difficult to form a liquid film of DIW at a peripheral edge of the substrate. See, for example, Japanese Laid-Open Patent Publication No. 2009-59895.

### SUMMARY

According to the present disclosure, there is provided a substrate liquid processing method that includes: forming a liquid film of a processing liquid having a diameter smaller than that of the substrate on a surface of a substrate by providing the processing liquid to a central portion of the surface of the substrate from a first nozzle while rotating the substrate around a vertical axis in a horizontal posture; supplying, from a second nozzle, a processing liquid, which is the same as the processing liquid supplied from the first nozzle, to a peripheral edge of the liquid film of the processing liquid formed on the surface by the first nozzle; and moving a position of supplying the processing liquid from the second nozzle to the surface of the substrate toward a peripheral edge of the substrate and as a result, expanding the liquid film of the processing liquid toward the peripheral edge of the substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional view schematically illustrating a configuration of a substrate liquid processing apparatus in accordance with an exemplary embodiment of the present disclosure.

FIG. 2 is a horizontal cross-sectional view of the substrate liquid processing apparatus illustrated in FIG. 1.

FIGS. 3A to 3D are schematic perspective views for describing a rinse processing process.

FIG. 4 is a plan view for describing the supply of a rinse liquid from a second nozzle in the rinse processing process.

FIGS. 5A and 5B are schematic views for describing an exemplary embodiment for supplying DIW liquid droplets to a central portion of a substrate in the rinse processing process.

FIG. 6 is a schematic side view for describing an exemplary embodiment for supplying DIW vapor to a central portion of a substrate in the rinse processing process

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

The present disclosure provides a technology capable of reducing a supply amount of a processing liquid and particles in a process of covering an entire surface of a substrate with the processing liquid.

According to an aspect of the present disclosure, there is provided a substrate liquid processing method that includes: forming a liquid film of a processing liquid having a diameter smaller than that of the substrate on a surface of a substrate by providing the processing liquid to a central portion of the surface of the substrate from a first nozzle while rotating the substrate around a vertical axis in a horizontal posture; supplying, from a second nozzle, a processing liquid, which is the same as the processing liquid supplied from the first nozzle, to a peripheral edge of the liquid film of the processing liquid formed on the surface by the first nozzle; and moving a position of supplying the processing liquid from the second nozzle to the surface of the substrate toward a peripheral edge of the substrate and as a result, expanding the liquid film of the processing liquid toward the peripheral edge of the substrate.

In the substrate liquid processing method, when viewed from a top, an ejection direction of the processing liquid from the second nozzle follows a flow direction of the processing liquid from the first nozzle at a position where the processing liquid from the second nozzle arrives at the surface of the substrate.

The substrate liquid processing method may further include: prior to the forming of the liquid film of the processing liquid on the surface of the substrate, performing a chemical liquid processing on the substrate by supplying the chemical liquid to the central portion of the surface of the substrate to form a liquid film on the surface of the substrate. The processing liquid is a rinse liquid formed of de-ionized water.

In the substrate liquid processing method, the chemical liquid processing enhances a hydrophobic property of the surface of the substrate after the chemical liquid processing as compared to a hydrophobic property of the surface of the substrate prior to the chemical liquid processing.

In the substrate liquid processing method, a moving speed of the second nozzle is equal to an expanding speed of the processing liquid by a centrifugal force.

In the substrate liquid processing method, an ejection rate of the processing liquid from the second nozzle is lower than an ejection rate of the processing liquid from the first nozzle.

In the substrate liquid processing method, in the forming of the liquid film on the surface of the substrate, the processing liquid is ejected toward the substrate from the first nozzle in a form of a continuous liquid flow.

In the forming of the liquid film on the surface of the substrate, the processing liquid is ejected toward the substrate from the first nozzle in a form of liquid droplets.

In the substrate liquid processing method, in the forming of the liquid film on the surface of the substrate, the processing liquid is ejected toward the substrate from the first nozzle in a form of vapor, and the vapor is condensed to liquid on the substrate.

The substrate liquid processing method further includes: further including supplying a cooling liquid to a rear surface of the substrate so as to facilitate the condensation of the vapor.

According to another aspect of the present disclosure, there is provided a substrate liquid processing apparatus that includes: a substrate holding unit configured to hold the substrate in a horizontal posture; a rotary drive unit configured to rotate the holding unit; a first nozzle configured to eject a processing liquid toward the substrate held by the holding unit; a second nozzle configured to eject a processing liquid toward the substrate held by the holding unit; a nozzle drive unit configured to move the second nozzle; and a control unit. The control unit is configured to control an operation of the substrate liquid processing apparatus to execute: a process of forming a liquid film of a processing liquid having a diameter smaller than that of the substrate on a surface of a substrate by providing the processing liquid to a central portion of the surface of the substrate from a first nozzle while rotating the substrate around a vertical axis in a horizontal posture; a process of supplying, from a second nozzle, a processing liquid, which is the same as the processing liquid supplied from the first nozzle, to a peripheral edge of the liquid film of the processing liquid formed on the surface by the first nozzle; and a process of moving a position of supplying the processing liquid from the second nozzle to the surface of the substrate toward a peripheral edge of the substrate and as a result, expanding the liquid film of the processing liquid toward the peripheral edge of the substrate.

In the substrate liquid processing apparatus, when viewed from a top, an ejection direction of the processing liquid from the second nozzle follows a flow direction of the processing liquid from the first nozzle at a position where the processing liquid from the second nozzle arrives at the surface of the substrate.

The substrate liquid processing apparatus may further include a third nozzle configured to eject a chemical liquid toward the substrate held by the holding unit. The processing liquid is a rinse liquid formed of de-ionized water, and the control unit causes, prior to the process of forming the liquid film on the surface of the substrate, the substrate liquid processing apparatus to perform a chemical liquid processing on the substrate by supplying the chemical liquid to the central portion of the surface of the substrate to form a liquid film on the surface of the substrate.

In the substrate liquid processing apparatus, the first nozzle is configured to eject the processing liquid toward the substrate from the first nozzle in a form of a continuous liquid flow.

In the substrate liquid processing apparatus, the first nozzle is configured to eject the processing liquid toward the substrate from the first nozzle in a form of liquid droplets.

In the substrate liquid processing apparatus, the first nozzle is configured to eject the processing liquid toward the substrate from the first nozzle in a form of vapor, and the vapor is condensed to liquid on the substrate.

The substrate liquid processing apparatus may further include a cooling liquid nozzle configured to supply a cooling liquid to a rear surface of the substrate so as to facilitate the condensation of the vapor.

According to still another aspect of the present disclosure, there is provided a non-transitory computer readable storage medium storing a computer-readable program that is executable by a control computer of a substrate liquid processing apparatus, and when executed, causes the control computer to control the substrate liquid processing apparatus to execute a substrate liquid processing method. The substrate liquid processing method includes: forming a liquid film of a processing liquid having a diameter smaller than that of the substrate on a surface of a substrate by providing the processing liquid to a central portion of the surface of the substrate from a first nozzle while rotating the substrate around a vertical axis in a horizontal posture; supplying, from a second nozzle, a processing liquid, which is the same as the processing liquid supplied from the first nozzle, to a peripheral edge of the liquid film of the processing liquid formed on the surface by the first nozzle; and moving a position of supplying the processing liquid from the second nozzle to the surface of the substrate toward a peripheral edge of the substrate and as a result, expanding the liquid film of the processing liquid toward the peripheral edge of the substrate.

According to the present disclosure, since the processing liquid from the second nozzle attracts the film of the processing liquid supplied from the first nozzle toward the peripheral edge of the substrate, the entire surface of the substrate may be covered with the liquid film of the processing liquid while reducing a total use amount of the processing liquid. Further, since the entire surface of the substrate may be covered with the processing liquid film, particles may be reduced.

Hereinafter, an exemplary embodiment of the present disclosure will be described with reference to the accompanying drawings. First, descriptions will be made on an overall configuration of a substrate liquid processing apparatus. The substrate liquid processing apparatus may include a spin chuck (a substrate holding unit) 20 configured to hold a substrate such as a semiconductor wafer (hereinafter, simply referred to as a “wafer W”) in a horizontal posture and to be rotatable around a vertical axis. The spin chuck 20 includes a disc-shaped base 21, and a plurality of holding members 22 disposed at a peripheral edge of the disc-shaped base 21 and configured to hold and release the wafer W. The spin chuck 20 is rotationally driven around the vertical axis by a rotary drive unit 24 having a motor. A cup 26 is disposed around the spin chuck 20 so as to receive a processing liquid scattering to the outside of the wafer W. Components of the substrate liquid processing apparatus such as, for example, the spin chuck 20 and the cup 26, are accommodated within a housing 10. The housing 10 is formed with a carry-in/carry-out port 11 in one side wall thereof to carry the wafer W into or out of the housing 10 and the carry-in/carry-out port 11 is provided with a shutter 12.

The substrate liquid processing apparatus may include a cleansing liquid nozzle 30 configured to supply a chemical liquid or de-ionized water to the wafer W, a drying liquid nozzle 31 configured to supply a drying liquid to the wafer W, and a gas nozzle 32 configured to supply an inert gas to the wafer W. The cleansing liquid nozzle 30, the drying liquid nozzle 31, and the gas nozzle 32 are attached to a first nozzle arm 34A via a first elevation mechanism 35A which includes, for example, an air cylinder. The first nozzle arm 34A may be moved by a first arm drive mechanism 36A along a first guide rail 37A which extends in a horizontal direction. Accordingly, the cleansing liquid nozzle 30, the drying liquid nozzle 31, and the gas nozzle 32 may be linearly moved from a position above a central portion of the wafer W to a position above a peripheral edge of the wafer W in a radial direction of the wafer W. Further, the cleansing liquid nozzle 30, the drying liquid nozzle 31, and the gas nozzle 32 may be positioned at a retreat position which is located outside the cup 26 when viewed from the top, and further moved up and down. The cleansing liquid nozzle 30, the drying liquid nozzle 31, and the gas nozzle 32 may be arranged along a moving direction of the first nozzle arm 34A such that each of the cleansing liquid nozzle 30, the drying liquid nozzle 31, and the gas nozzle 32 may be placed just above the central portion of the wafer W held by the spin chuck 20.

A chemical liquid supply mechanism 40 is connected to the cleansing liquid nozzle 30. The chemical liquid supply mechanism 40 include a diluted hydrofluoric acid (“DHF”) supply source 41 configured to supply DHF as a chemical liquid, a DHF supply line 42 configured to connect the DHF supply source 41 to the cleansing liquid nozzle 30, and a valve device 43 including, for example, an opening/closing valve and a flow control valve which are installed in the DHF supply line 42. Thus, the chemical liquid supply mechanism 40 may supply the DHF to the cleansing liquid nozzle 30 at a flow rate controlled by the valve device 43.

The cleansing liquid nozzle 30 is connected to a first rinse liquid supply mechanism 50. The first rinse liquid supply mechanism 50 includes a DIW supply source 51 configured to supply DIW as a rinse liquid, a DIW supply line 52 configured to connect the DIW supply source 51 to the cleansing liquid nozzle 30, and a valve device 53 including, for example, an opening/closing valve and a flow control valve which are installed in the DIW supply line 52. Thus, the rinse liquid supply mechanism 50 may supply the DIW to the cleansing liquid nozzle 30 at a flow rate controlled by the valve device 53.

A drying liquid supply mechanism 60 is connected to the drying liquid nozzle 31. The drying liquid supply mechanism 60 includes an isopropyl alcohol (“IPA”) supply source 61 configure to supply IPA as a drying liquid, an IPA supply line 62 configured to connect the IPA supply source 61 to the drying liquid nozzle 31, and a valve device 63 including, for example, an opening/closing valve and a flow control valve which are installed in the IPA supply line 62. Thus, the drying liquid supply mechanism 60 may supply the IPA to the drying liquid nozzle 31 at a flow rate controlled by the valve device 63. Since the IPA is miscible with DIW, the IPA may be easily replaced for DIW. Further, since the IPA is more volatile than DIW, the IPA may efficiently dry DIW. Accordingly, the IPA may be properly used as the drying liquid. In addition, since the IPA has a lower surface tension than DIW, the IPA may prevent collapse of a micro-pattern having a high aspect ratio. The drying liquid is not limited to the IPA and any other organic solvent may be employed as the drying liquid as long as the organic solvent exhibits the above-mentioned characteristics.

A drying gas supply mechanism 70 is connected to the gas nozzle 32. The drying gas supply mechanism 70 includes a nitrogen gas supply source 71 configured to supply nitrogen gas as a drying gas, a nitrogen gas supply line 72 configured to connect the nitrogen gas supply source 71 to the gas nozzle 32, and a valve device 73 including, for example, an opening/closing valve and a flow control valve installed in the nitrogen gas supply line 72. As for the drying gas, a gas with a low oxygen concentration and low humidity may be used. Besides the nitrogen gas, an inert gas may be used.

The substrate liquid processing apparatus is provided with a rinse liquid nozzle 33 which is configured to supply DIW to the wafer W as a rinse liquid. The rinse liquid nozzle 33 is attached to a second nozzle arm 34B via a second elevation mechanism 35B which includes, for example, an air cylinder. The second nozzle arm 34B may be moved by a second arm drive mechanism 36B along a second guide rail 37B which extends in a horizontal direction. Accordingly, the rinse liquid nozzle 33 may be linearly moved in a radial direction of the wafer W from a position above the central portion of the wafer W to a position above the peripheral edge of the wafer W. Further, the rinse liquid nozzle 33 may be placed at a retreat position which is located outside the cup 26 as viewed from the top and further, may be moved up and down. To avoid interference with each other, the first nozzle arm 34A may be moved in to the right area of the drawing with reference to the central of the wafer W while the second nozzle arm 34B may be moved the left area of the drawing with reference to the central portion of the wafer W.

A second rinse liquid supply mechanism 80 is connected to the rinse liquid nozzle 33. The second rinse liquid supply mechanism 80 includes a DIW supply source 81 configured to supply DIW as a rinse liquid, a DIW supply line 82 configured to connect the DIW supply source 81 to the rinse liquid nozzle 33, and a valve device 83 including, for example, an opening/closing valve and a flow control valve which are installed in the DIW supply line 82. Thus, the second rinse liquid supply mechanism 80 may supply the DIW to the rinse liquid nozzle 33 at a flow rate controlled by the valve device 83.

A control unit 90 including a computer controls the operations of the rotary drive unit 24, the arm drive mechanisms 36A and 36B, the chemical liquid supply mechanism 40, the first rinse liquid supply mechanism 50, the drying liquid supply mechanism 60, the drying gas supply mechanism 70, and the second rinse liquid supply mechanism 50. As shown in FIG. 1, an input/output device 91 such as, for example, a keyboard or a display, is connected to the control unit 90. The keyboard may be used by, for example, a process administrator, to input an operation command so as to manage the substrate liquid processing apparatus. The display may visualize and display, for example, an operating situation of the substrate liquid processing apparatus. The control unit 90 may access a storage medium 92 which is stored with, for example, a program configured to execute a processing carried out by the substrate liquid processing apparatus. The storage medium 92 may be constituted with a known storage medium such as, for example, a memory such as ROM (read only memory) or RAM (random access memory), or a disc-type medium such as a hard disc, a CD-ROM, a DVD-ROM, or a flexible disc. When the control unit 90 executes the computer program stored in the storage medium, a processing on the wafer W may be performed in the substrate liquid processing apparatus.

Next, descriptions will be made on the operations of the substrate liquid processing apparatus. The operations described below may be controlled using a control signal generated by the control unit 90 when the program stored in the storage medium 92 is executed.

First, the shutter 12 is opened and then a wafer W held by a conveying arm (not shown) is carried into the housing 10 through the carry-in/carry-out port 11. Thereafter, the wafer W is delivered from the conveying arm to the spin chuck 20 and held by the holding member 22 of the spin chuck 20.

[Chemical Liquid Processing Process]

Thereafter, the cleansing liquid nozzle 30 placed at the retreat position is moved by the first arm drive mechanism 36A to a position just above the central portion of the wafer held by the spin chuck 20. In addition, the spin chuck 20 holding the wafer W is rotated by the rotary drive unit 24. At this state, DHF is ejected by the chemical liquid supply mechanism 40 to the central portion of the wafer W through the cleansing liquid nozzle 30 so as to perform a chemical liquid processing (chemical liquid cleansing) on the wafer W. The ejected DHF spreads out over the entire surface of the wafer W by the centrifugal force, forming a liquid film of DHF on the surface of the wafer W. At this time, a rotation speed of the wafer W may be, for example, in a range of about 10 rpm to 500 rpm. The wafer W is continuously rotated until the drying process for the wafer W is completed.

[Rinse Processing Process]

After the chemical liquid processing is carried out for a predetermined length of time, a rinse processing process is performed. The rinse processing process will be described in detail with reference to FIGS. 3A to 3D and FIG. 4. After the chemical liquid processing is performed for the predetermined length of time, the supply of the DHF liquid from the chemical liquid supply mechanism 40 is stopped. Instead, DIW is ejected toward the central portion of the surface of the wafer W (the position of a point P1 in FIG. 4) by the first rinse liquid supply mechanism 50 through the cleansing liquid nozzle 30 placed just above the central portion of the wafer W. At a time point just before the DIW is ejected from the cleansing liquid nozzle 30, the surface of the wafer W is covered with a HDF liquid film. In the rinse processing process, the rotation speed of the wafer W is, for example, in a range of about 200 rpm to 400 rpm. In this operation, the rotation speed may be adjusted to 300 rpm. The rotation speed of the wafer W may be determined such that no problem is caused even if the processing liquid scatters out of the wafer W at the rotation speed. The ejection rate of DIW from the cleansing liquid nozzle 30 may be set to, for example, 2.5 L/min. The rotation speed of the wafer W and the ejection rate of DIW are maintained constantly during the rinse processing process. However, the rotation speed of the wafer W and the ejection rate of DIW may vary during the rinse processing process.

The DIW which arrived at (dropped to) the surface of the rotating wafer W is subjected to a centrifugal force and a friction force. Consequently, the DIW may spread out and flow outwardly in a spiral form as shown in FIG. 4. As a result, a circular region on the wafer W over a predetermined distance from the center of the wafer W is covered with a continuous liquid film L of DIW. In the circular region, the DHF is replaced with DIW. The size of the circular region may be varied depending on a degree of hydrophobic property of the wafer W, the ejection rate of DIW, and the rotation speed of the wafer. Since the surface of the wafer W is hydrophobic due to the previous DHF cleansing process, under the above-mentioned condition of the ejection rate of DIW and the rotation speed of the wafer W, the circular region having a diameter (e.g., 80 mm) corresponding to approximately one half of the diameter of a 12 inch (300 mm) wafer W having a diameter of 12 inch (300 mm) is covered with the liquid film L of DIW (see, e.g., FIG. 3A). Outside the circular region covered with the liquid film L of DIW, the liquid film of DHF remains on the surface of the wafer W. However since DIW is not able to form a continuous liquid film, the DIW flows outwardly in a form of streaks. The flow of DIW in the form of streaks is not illustrated. When the ejection rate of DIW from the cleansing liquid nozzle 30 or the rotation speed of the wafer W is increased, the size (diameter) of the circular region covered with the liquid film L of DIW may be increased. However, as described in the “Background” section, when the ejection rate of DIW or the rotation speed of the wafer W is increased, the use amount of DIW may be increased and undesired scattering of DIW may be caused. When the state where only the circular central region of the wafer W is covered with the liquid film L of DIW is continued, in the region uncovered by the liquid film of DIW, DHF is partially substituted with the DIW flowing in the form of streaks or DHF is centrifugally separated, thereby exposing the surface of the surface of the wafer W. When such a situation occurs, particles may be produced.

Thus, in the present exemplary embodiment, as illustrated in FIG. 3A, DIW is ejected toward the central portion of the wafer W from the cleansing liquid nozzle 30. Substantially at the same time when a circular region of which the diameter is smaller than the wafer W is covered with a liquid film L of DIW, the ejection of DIW is initiated toward the peripheral edge portion of the circular liquid film L of DIW (position of point P2 of FIG. 4 slightly inside of the peripheral edge) from the rinse liquid nozzle 33 as illustrated in FIG. 3B while maintaining the ejection rate of DIW from the cleansing liquid nozzle 30. The ejection rate of DIW from the rinse liquid nozzle 33 may be set to, for example, 0.5 L/min. In addition, prior to ejecting the DIW from the rinse liquid nozzle 33, the rinse liquid nozzle 33 is moved by the second arm drive mechanism 36B from the retreat position to an ejection initiation position where the DIW is ejected toward point P2 of FIG. 4. The discharge initiation position is determined in advance by performing a test in which the DIW is ejected from the cleansing liquid nozzle 30 to the central portion of a wafer W to actually form a liquid film.

After the ejection of the DIW from the rinse liquid nozzle 33 is initiated, the rinse liquid nozzle 33 is moved outwardly in the radial direction in such a manner that the arrival position of DIW ejected from the rinse liquid nozzle 33 on the surface of the wafer W is moved outwardly in the radial direction as illustrated in FIGS. 3C and 3D, while maintaining the ejection rates of DIW from the cleansing liquid nozzle 30 and the rinse liquid nozzle 33. Then, the circular liquid film L of DIW is drawn by the radially outward movement of the rinse liquid nozzle 33, thereby spreading out. At this time, in the outside of the region where the liquid film L of DIW is formed, only the liquid film of DHF remains and the liquid film L of DIW still flows outwardly in the form of streaks. The radially outward moving speed of the rinse liquid nozzle 33 is constantly maintained, for example, at about 8 mm/sec. However, the moving speed may be varied. When the radially outward moving speed of the rinse liquid nozzle 33 is too high, the expansion of the liquid film L of DIW by the centrifugal force may not follow the movement of the rinse liquid nozzle 33 and thus, fracture of the liquid film may be caused between the cleansing liquid nozzle 30 and the rinse liquid nozzle 33. Accordingly, it is desirable that the radially outward moving speed of the rinse liquid nozzle 33 is not higher than the radially outward expansion speed of the liquid film L of DIW region by the centrifugal force.

When the arrival position of DIW ejected from the rinse liquid nozzle 33 on the surface of the wafer W arrives at a peripheral edge portion of the wafer W (slightly inside the peripheral edge of the wafer W), the entire surface of the wafer W may be covered with a continuous liquid film L of DIW as illustrated in FIG. 3D. When such a state is obtained, the movement of the rinse liquid nozzle 33 is stopped, and the ejection amount of DIW from each of the cleansing liquid nozzle 30 and the rinse liquid nozzle 33 is maintained such that the entire surface of the wafer W may be continuously covered with the continuous liquid film L of DIW. When this state is continued for a predetermined length of time, DHF is substituted with the DIW over the entire surface of the wafer W. That is, as described above, when the DIW was ejected from the cleansing liquid nozzle 30 to the central portion of the wafer W at a flow rate which is insufficient for covering the entire surface of the wafer W and thus, a center side circular region of the surface of the wafer W was covered with the liquid film of DIW, DIW is instantly ejected by the rinse liquid nozzle 33 to the peripheral edge of the liquid film of DIW formed by the DIW supplied from the cleansing liquid nozzle 30 and then the ejection position of DIW on the wafer W from the rinse liquid nozzle 33 is gradually moved toward the peripheral edge of the wafer W. As such, the outer region of the wafer W may be prevented from being exposed to the surrounding atmosphere. As a result, it is possible to prevent occurrence of particles, which may be caused when the surface wetted by the chemical liquid is exposed to the surrounding atmosphere, using a totally small ejection amount of DIW.

In order to prevent the flow of DIW forming the liquid film L from being disturbed in the entire period from the state as illustrated in FIG. 3B to the state as illustrated in FIG. 3D, it is desirable to eject DIW to the liquid film L of DIW from the rinse liquid nozzle 33. As illustrated in FIG. 4, the DIW ejected to the central portion P1 of the wafer W from the rinse liquid nozzle 33 flows outwardly in a spiral form. At this time, it is desired to eject the DIW to be directed obliquely downward from the rinse liquid nozzle 33 so that the direction of DIW ejected from the rinse liquid nozzle 33 may follow the spiral flow direction at the position P2 where the DIW discharged from the cleansing liquid nozzle arrives at the surface of the wafer W (the surface of the liquid film L of DIW) when viewed from the top. By doing this, the action of expanding the liquid film L forming region accompanied with the radially outward movement of the rinse liquid nozzle as illustrated in FIGS. 3B to 3D may be smoothly induced. Further, the spiral flow direction at the position P2 and the direction of DIW ejected from the rinse liquid nozzle 33 do not have to completely coincide with each other and may cross with an angle of not more than ±45 degrees.

In addition, the flow direction of DIW forming the liquid film L at the peripheral edge portion (i.e., the arrival position of the DIW ejected from the rinse liquid nozzle 33) of the liquid film L is changed little in the process of expanding the liquid film L. That is, at the peripheral edge portion of the liquid film L, the angle of the flow direction of the DIW forming the liquid film L in relation to the circumferential direction of the peripheral edge of the circular liquid film is relatively small and the angle is changed little while the liquid film L is being expanded. Therefore, even if, using a linearly moving nozzle arm (the second nozzle arm 34B), the rinse liquid nozzle 33 is attached to the second nozzle arm 34B such that the ejection angle of the rinse liquid nozzle 33 cannot be adjusted, the above-described actions may be induced substantially without hindrance. Further, even if, using a rotationally moving nozzle, the rinse liquid nozzle 33 is attached to the second nozzle arm 34B such that the ejection angle of the rinse liquid nozzle 33 cannot be adjusted, the above-described actions may be induced substantially without hindrance, except for a case where the nozzle arm is extremely short. However, the rinse liquid nozzle may be attached to the nozzle arm such that the ejection angle of the rinse liquid nozzle can be adjusted so as to change the direction of the rinse liquid nozzle in the course of expanding the liquid film in such a manner that the relationship between the ejection direction of DIW from the rinse liquid nozzle and the direction of the spiral flow of DIW may be optimized.

[Drying Process]

After the rinse processing process is performed for a predetermined length of time, the ejection of DIW from the cleansing liquid nozzle 30 and the rinse liquid nozzle 33 is stopped. The rinse liquid nozzle 33 is moved to the retreat state. Thereafter, the rotation speed of the wafer W is adjusted to be in a range of about 100 rpm to 500 rpm and the drying liquid nozzle 31 may be placed just above the central portion of the wafer W such that IPA is ejected to the central portion of the surface of the wafer W through the drying liquid nozzle 31 using the drying liquid supply mechanism 60. The drying liquid nozzle 31 executes a reciprocating motion (a scanning motion) between the position above the central portion and the position above the peripheral edge of the wafer W while ejecting the IPA. As a result, the DIW remaining on the surface of the wafer W is substituted with the IPA.

Subsequently, the rotation speed of the wafer W is adjusted to be in the range of about 500 rpm to 800 rpm, the IPA is ejected from the drying liquid nozzle 31, nitrogen gas is ejected from the gas nozzle 32, and the drying liquid nozzle 31 and the gas nozzle 32 are moved (scanning) from a position corresponding to the central portion of the wafer W to a position corresponding to the peripheral edge of the wafer W. At this time, the drying liquid nozzle 31 is positioned in front of the gas nozzle 32 in the moving direction. As a result, the wafer W is dried.

If the wafer W was dried, the rotation of the wafer W is stopped, and then, the wafer W is carried out of the substrate liquid processing apparatus in the sequence opposite to the sequence of carrying the wafer W into the substrate liquid processing apparatus.

Next, descriptions will be made on results of a test conducted so as to confirm the effects of the exemplary embodiments described above. In the test, a substrate liquid processing apparatus having a configuration which is approximately the same as that of the substrate liquid processing apparatus as shown in FIGS. 1 and 2. A 300 mm bare silicon wafer was hold and rotated by the spin chuck. LAL 5000 (trademark name of a buffered hydrofluoric acid based solution available from Stella Chemifa Corporation) was supplied to the wafer. As a result, a natural oxide film on the surface of the wafer was removed and a hydrophobic surface was obtained. The contact angle of the surface in relation to the DIW was 77 degrees.

DIW rinse processings were performed on wafers having a hydrophobic surface according to the conventional method and the method of the exemplary embodiments described above. In the conventional method, DIW was ejected to the central portion of each wafer only using the cleansing liquid nozzle 30 while the wafer is being supported and rotated by the spin chuck and an ejection rate of DIW, which ensures that a liquid film L is securely formed over the entire surface of each wafer, was investigated by changing the ejection rate of DIW. In the method of the present disclosure, DIW was supplied from the rinse liquid nozzle 33 at an ejection rate of 0.5 L/min and the total ejection rate of DIW (the total sum of the ejection rate from the rinse liquid nozzle 33 and the ejection rate from the cleansing liquid nozzle 30), which ensures that a liquid film L is securely formed over the entire surface of each wafer, was investigated while changing the ejection rate of DIW from the cleansing liquid nozzle 30 to the central portion of each wafer. The rotation speed of the wafers was set to 300 rpm.

The total ejection rate of DIW required for ensuring the liquid film L to be securely formed on the entire surface of each wafer was substantially reduced to 3.0 L/min in the method of the present disclosure as compared to 4.0 L/min in the conventional method.

From the test results, it was found that, when the method of the present disclosure is used, the total amount of DIW required for a rinse processing process may be reduced. Further, it is obvious that, since the ejection amount from the cleansing liquid nozzle 30 that ejects DIW to the central portion of the wafer W may be reduced, the DIW may be suppressed from scattering from the wafer W.

Although the rinse processing process in the exemplary embodiment described above were performed on the wafers having a hydrophobic surface obtained by removing a natural oxide film using a hydrofluoric acid based solution, the present disclosure is not limited thereto. The rinse processing process according to the exemplary embodiments described above may be especially useful when the rinse processing process is performed after a hydrophobic processing is performed actively so as to form a hydrophobic surface on a substrate such as a wafer. As for a hydrophobic processing liquid in such a hydrophobic processing, for example, a silylating agent such as dimethylaminotrimethylsilane (TMSDMA), dimethyl(dimethylamino)silane (DMSDMA), 1,1,3,3-tetramethylsilane (TMDS), hexamethyldisilazane (HMDS), or a fluoropolymer based chemical liquid may be used.

Moreover, although a rinse processing process using DIW as a rinse liquid is continuously performed after a chemical liquid processing (DHF cleansing processing) in the above-described exemplary embodiment, the present disclosure is not limited thereto. For example, only a single DIW cleansing processing may be performed (without a pre-process followed by the DIW cleaning processing). In such a case, it is also possible to form a liquid film of DIW over an entire surface of a wafer W using a small ejection amount of DIW, reducing the DIW consumption. Further, it is also possible to reduce particles.

Moreover, in the exemplary embodiment described above, in the rinse processing process, DIW as a processing liquid is continuously ejected to the central portion of a wafer from a first processing liquid nozzle (the cleansing liquid nozzle 30), and DIW as a processing liquid is ejected while moving a second processing liquid nozzle (the rinse liquid nozzle 33) toward the peripheral edge of the wafer. However, the processing liquids ejected from the two processing liquid nozzles 30 and 33 are not limited to the DIW rinse liquid but may be a different chemical liquid such as, for example, an acidic chemical liquid, an alkaline chemical liquid, an organic solvent, or a developer. In such a case, effects of reducing a consumption of a processing liquid, suppressing liquid spattering, and reducing particles may be expected. However, in this case, processing liquids such as the acidic chemical liquid, the alkaline chemical liquid, the organic solvent, and the developer may be supplied to a dried wafer W using the two processing liquid nozzles, without being limited to supplying the processing liquids to a wet surface of a wafer W.

In addition, the substrate to be processed may be, for example, a glass substrate or a ceramic substrate without being limited to a semiconductor wafer.

In addition, in the exemplary embodiment described above, in the rinse processing process, the cleansing liquid nozzle 30 ejects DIW toward the central portion of the wafer W in a form of a continuous water flow (liquid flow) LC as illustrated in FIG. 5A so as to form a circular liquid film at a central region of the wafer W, as illustrated in FIG. 3A. However, the present disclosure is not limited to this. As another exemplary embodiment, for example, a circular liquid film may be formed at the central region by providing a cleansing liquid nozzle 130 configured as a two-fluid nozzle instead of the cleansing liquid nozzle 30 as illustrated in FIG. 5B, and ejecting DIW toward the central portion of the wafer W in a form of liquid droplets LD from the cleansing liquid nozzle 130.

For example, as illustrated in FIG. 5B, inside the cleansing liquid nozzle 130, a flow path 130 in which a gas flows, is provided and a DIW flow path 132 joined to the flow path 131 is also provided. A gas supply mechanism 140 configured to supply a gas for atomizing DIW or generating DIW liquid droplets (here, nitrogen gas) is connected to the flow path 131. The gas supply mechanism 140 includes, for example, a gas supply source 141, a gas supply line 142 configured to connect the gas supply source 141 to the flow path 131, and a valve device 143 including an opening/closing vale and a flow control valve which are installed in the gas supply line 142. Accordingly, the gas supply mechanism 140 may supply the gas to the flow path 131 of the cleansing liquid nozzle 130 at a controlled flow rate. A rinse liquid supply mechanism 50 which is the same as that of FIG. 1 is connected to the flow path 132.

When DIW is introduced into the flow path 131, in which the gas is flowing from the flow path 132, the introduced DIW is atomized and ejected from an ejection port 133 in a form of liquid droplets having a size of, for example, about 50 μm, toward the surface of the wafer W. The liquid droplets colliding against the surface of the wafer W are connected with each other such that a liquid film L is formed at a central region of the wafer W, as illustrated in FIG. 3A. When the liquid film L is formed, DIW is ejected from the rinse liquid nozzle 33 in the sequence described above with reference to FIGS. 3B to 3D and the rinse liquid nozzle 33 is moved outward. Thus, the liquid film L of DIW may be formed over the entire surface of the wafer W.

Actions obtained when using the cleansing liquid nozzle 130 may be understood from the fact that the cleansing liquid nozzle 30 in FIGS. 3A to 3D is considered as the cleansing liquid nozzle 130. Even when the cleansing liquid nozzle 130 is used, a similar operation may be performed by the rinse liquid nozzle 33.

The ejection rate of DIW when the DIW is ejected in the form of liquid droplets LD may be substantially reduced as compared with the ejection rate of DIW when the DIW is ejected in the form of continuous water flow LC. For example, as described above, when the latter is about 1 L/min, the former may be reduced to about 0.1 L/min which is about one tenth of the latter.

However, in such a case, as compared with that formed by supplying the continuous water flow LC to the wafer W as illustrated in FIG. 5A, the thickness of the liquid film L formed on the surface of the wafer W may be reduced and thus, the region where the liquid film L is formed may be narrowed. Considering this, the radial position of initially supplying DIW to the wafer W from the rinse liquid nozzle 33 (the position illustrated in FIG. 3B) should be moved inwardly and the ejection amount of DIW from the rinse liquid nozzle 33 should be increased.

However, when the ejection rate of DIW from the cleansing liquid nozzle 130 is set to 0.1 L/min, the ejection rate of DIW from the rinse liquid nozzle 33 which is required for covering the entire surface of the wafer W with the liquid film L is, for example, about 1 L/min That is, the sum of the ejection rates of DIW is about 1.1 L/min. This value is substantially smaller than (about ⅓ of) the total ejection rate of 3.0 L/min obtained when the cleansing liquid nozzle 30 is used (as described above, the ejection rate from the cleansing liquid nozzle 30 is 2.5 L/min and the ejection rate from the rinse liquid nozzle 33 is 0.5 L/min) That is, when the liquid droplets of DIW are supplied to the central portion of the wafer W to form a liquid film at the central region of the wafer W, the overall consumption of DIW may be reduced.

As still another exemplary embodiment, a cleansing liquid nozzle (vapor nozzle) 230 configured to eject DIW to the central portion of the wafer W in a form of vapor V as illustrated in FIG. 6 may be provided instead of the cleansing liquid nozzle 30 configured to supply DIW to the wafer W in the form of a continuous water flow illustrated in FIG. 5A. A vapor supply mechanism 240 is connected to the cleansing liquid nozzle 230. The vapor supply mechanism 240 includes a vapor supply source 241 configured to supply vapor of de-ionized water (DIW) V as the vapor, a vapor supply line 242 configured to connect the vapor supply source 241 to the vapor nozzle 230, and a valve device 241 including, for example, an opening/closing valve and a flow control valve which are installed in the vapor supply line 242. Accordingly, the vapor supply mechanism 240 may supply the DIW vapor to the cleansing liquid nozzle 230 at a controlled flow rate.

In order to facilitate the condensation of the vapor V on the surface of the wafer W, a cooling liquid nozzle 250 configured to supply a cooling liquid C to the rear surface of the wafer W is provided below the central portion of the bottom surface of the wafer W. In the illustrated example, the cooling liquid nozzle 250 is formed by a top end opening of a cooling liquid flow path 251 extending through the base 21 and the rotation shaft of the spin chuck 20. A cooling liquid supply mechanism 260 is connected to the cooling liquid flow path 251. The cooling liquid supply mechanism 260 includes a cooling liquid supply source 261 configured to supply, for example, DIW of a normal temperature as the cooling liquid C, a cooling liquid supply line 262 configured to connect the cooling liquid supply source 261 to the cleansing liquid nozzle 230, and a valve device 263 including, for example, an opening/closing valve and a flow control valve which are installed in the cooling liquid supply line 262. Accordingly, the cooling liquid supply mechanism 260 may supply the cooling liquid to the cleansing liquid nozzle 230 at a controlled flow rate.

When the DIW vapor V is supplied to the central portion of the surface of the wafer W, the vapor V is deprived of heat to the wafer W and thus, dewed (condensed) to form liquid droplets. The liquid droplets are connected with each other to form a liquid film L in a central region of the wafer W as illustrated in FIG. 3A. When the liquid film L is formed, DIW is ejected from the rinse liquid nozzle 33 in the sequence described above with reference to FIGS. 3B to 3D and the rinse liquid nozzle 33 is moved outward. As a result, the liquid film L of DIW may be formed over the entire surface of the wafer W. In such a case, the ejection amount of DIW from the cleansing liquid nozzle 230 (the ejection amount converted into the amount of liquid) may also be substantially reduced. However, the present exemplary embodiment is similar to the exemplary embodiment of FIG. 5B in that the ejection rate of DIW from the rinse liquid nozzle 33 should be increased and the ejection initiation position of DIW from the rinse liquid nozzle 33 should be moved inward in the radial direction.

FIGS. 5B and 6 mainly illustrate modified portions in relation to the configuration of FIG. 1 so as to simplify the figures. Of course, among the components of the substrate liquid processing apparatus, the components illustrated in FIG. 1 but not illustrated in FIGS. 5B and 6 may be employed. In addition, in the exemplary embodiment of FIG. 1, the cleansing liquid nozzle 30 has a chemical liquid supply function by being connected to the chemical liquid supply mechanism 40. However, the cleansing liquid nozzle 130 illustrated in FIG. 5B may also be provided with the chemical liquid supply function. When the cleansing liquid nozzle 130 illustrated in FIG. 5B is provided, a separate nozzle dedicated for supplying a chemical liquid may be provided. When the cleansing liquid nozzle 230 illustrated in FIG. 6 is used, it is desirable to provide the separate nozzle dedicated for supplying a chemical liquid.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A substrate liquid processing method comprising:
forming a liquid film of a processing liquid having a diameter smaller than that of the substrate on a surface of a substrate by providing the processing liquid to a central portion of the surface of the substrate from a first nozzle while rotating the substrate around a vertical axis in a horizontal posture;
supplying, from a second nozzle, a processing liquid, which is the same as the processing liquid supplied from the first nozzle, to a peripheral edge of the liquid film of the processing liquid formed on the surface by the first nozzle; and
moving a position of supplying the processing liquid from the second nozzle to the surface of the substrate toward a peripheral edge of the substrate and as a result, expanding the liquid film of the processing liquid toward the peripheral edge of the substrate.

2. The substrate liquid processing method of claim 1, wherein, when viewed from a top, an ejection direction of the processing liquid from the second nozzle follows a flow direction of the processing liquid from the first nozzle at a position where the processing liquid from the second nozzle arrives at the surface of the substrate.

3. The substrate liquid processing method of claim 1, further comprising:
prior to the forming of the liquid film on the surface of the substrate, performing a chemical liquid processing on the substrate by supplying the chemical liquid to the central portion of the surface of the substrate to form a liquid film on the surface of the substrate,
wherein the processing liquid is a rinse liquid formed of de-ionized water.

4. The substrate liquid processing method of claim 3, wherein the chemical liquid processing enhances a hydrophobic property of the surface of the substrate after the chemical liquid processing as compared to a hydrophobic property of the surface of the substrate prior to the chemical liquid processing.

5. The substrate liquid processing method of claim 1, wherein a moving speed of the second nozzle is equal to an expanding speed of the processing liquid by a centrifugal force.

6. The substrate liquid processing method of claim 1, wherein an ejection rate of the processing liquid from the second nozzle is lower than an ejection rate of the processing liquid from the first nozzle.

7. The substrate liquid processing method of claim 1, wherein, in the forming of the liquid film on the surface of the substrate, the processing liquid is ejected toward the substrate from the first nozzle in a form of a continuous liquid flow.

8. The substrate liquid processing method of claim 1, wherein, in the forming of the liquid film on the surface of the substrate, the processing liquid is ejected toward the substrate from the first nozzle in a form of liquid droplets.

9. The substrate liquid processing method of claim 1, wherein, in the forming of the liquid film on the surface of the substrate, the processing liquid is ejected toward the substrate from the first nozzle in a form of vapor, and the vapor is condensed to liquid on the substrate.

10. The substrate liquid processing method of claim 9, further comprising:
supplying a cooling liquid to a rear surface of the substrate so as to facilitate the condensation of the vapor.

11. A substrate liquid processing apparatus, comprising:
a substrate holding unit configured to hold the substrate in a horizontal posture;
a rotary drive unit configured to rotate the holding unit;
a first nozzle configured to eject a processing liquid toward the substrate held by the holding unit;
a second nozzle configured to eject a processing liquid toward the substrate held by the holding unit;
a nozzle drive unit configured to move the second nozzle; and
a control unit,
wherein the control unit is configured to control an operation of the substrate liquid processing apparatus such that the substrate liquid processing apparatus executes:
a process of forming a liquid film of a processing liquid having a diameter smaller than that of the substrate on a surface of a substrate by providing the processing liquid to a central portion of the surface of the substrate from a first nozzle while rotating the substrate around a vertical axis in a horizontal posture;
a process of supplying, from a second nozzle, a processing liquid, which is the same as the processing liquid supplied from the first nozzle, to a peripheral edge of the liquid film of the processing liquid formed on the surface by the first nozzle; and
a process of moving a position of supplying the processing liquid from the second nozzle to the surface of the substrate toward a peripheral edge of the substrate and as a result, expanding the liquid film of the processing liquid toward the peripheral edge of the substrate.

12. The substrate liquid processing apparatus of claim 11, wherein, when viewed from a top, an ejection direction of the processing liquid from the second nozzle follows a flow direction of the processing liquid from the first nozzle at a position where the processing liquid from the second nozzle arrives at the surface of the substrate.

13. The substrate liquid processing apparatus of claim 11, further comprising:
a third nozzle configured to eject a chemical liquid toward the substrate held by the holding unit,
wherein the processing liquid is a rinse liquid formed of de-ionized water, and
the control unit causes, prior to the process of forming the liquid film on the surface of the substrate, the substrate liquid processing apparatus to perform a chemical liquid processing on the substrate by supplying the chemical liquid to the central portion of the surface of the substrate to form a liquid film on the surface of the substrate.

14. The subsequent liquid processing apparatus of claim 11, wherein the first nozzle is configured to eject the processing liquid toward the substrate from the first nozzle in a form of a continuous liquid flow.

15. The subsequent liquid processing apparatus of claim 11, wherein the first nozzle is configured to eject the processing liquid toward the substrate from the first nozzle in a form of liquid droplets.

16. The subsequent liquid processing apparatus of claim 11, wherein the first nozzle is configured to eject the processing liquid toward the substrate from the first nozzle in a form of vapor, and the vapor is condensed to liquid on the substrate.

17. The subsequent liquid processing apparatus of claim 16, further comprising:
a cooling liquid nozzle configured to supply a cooling liquid to a rear surface of the substrate so as to facilitate the condensation of the vapor.

18. A non-transitory computer readable storage medium storing a computer-readable program that is executable by a control computer of a substrate liquid processing apparatus, and when executed, causes the control computer to control the substrate liquid processing apparatus to execute a substrate liquid processing method,
wherein the substrate liquid processing method comprises:
forming a liquid film of a processing liquid having a diameter smaller than that of the substrate on a surface of a substrate by providing the processing liquid to a central portion of the surface of the substrate from a first nozzle while rotating the substrate around a vertical axis in a horizontal posture;
supplying, from a second nozzle, a processing liquid, which is the same as the processing liquid supplied from the first nozzle, to a peripheral edge of the liquid film of the processing liquid formed on the surface by the first nozzle; and
moving a position of supplying the processing liquid from the second nozzle to the surface of the substrate toward a peripheral edge of the substrate and as a result, expanding the liquid film of the processing liquid toward the peripheral edge of the substrate.
